(19) United States
(12) Patent Application Publication
(10) Pub. No.: US 2007/0146997 A1
(43) Pub. Date: Jun. 28, 2007

(54) Expandible housing for rack mounted device

(75) Inventor: Jimmy Grant Foster SR., Morrisville, NC (US)

Correspondence Address: IBM CORPORATION, PO BOX 12195, DEPT YXSA, BLDG 002, RESEARCH TRIANGLE PARK, NC, 27709, US

(73) Assignee: INTERNATIONAL BUSINESS MACHINES CORPORATION, ARMONK, NY (US)

(21) Appl. No.: 11/328,489

(22) Filed: Dec. 28, 2005

(51) Int. Cl. H05K 7/20

(52) U.S. Cl. 361/700

(57) ABSTRACT

An enclosure for a rack mounted electronic device is assembled using upper and lower housings which are adjustable one relative to the other to provide increases in enclosure height by fractional increments of a standard unit of height. By providing for fractional growth in height, a user is enabled to upgrade processor, memory and other components without the necessity of replacing the entirety of a device which is in use.

### FIELD AND BACKGROUND OF INVENTION

Recent advances in high volume server computer systems, typically rack mounted systems, have introduced advanced processors and operating systems capable of addressing significantly larger volumes of memory. Additionally, the advanced processors can in some models be fabricated with two or more processors on a die or on a common carrier and supported in a single socket, increasing the power and thermal demands placed on systems.

Rack optimized server systems typically have mechanical elements, such as the enclosure for the electronic elements, based on a incremental height of 1.75 inches, known to the industry as 1 U or 1 unit. The 1 U server is the one most impacted by the advances in processors, operating systems and memory. Users who stress their 1 U systems to maximum performance for extended periods of time will encounter thermal difficulties. In order to achieve the levels of performance desired while maintaining acceptable thermal limits, such users may find it necessary to replace their 1 U servers with 2 U servers, as prior to the present invention all rack mounted servers known to the inventors were incremented in height by the standard unit.

### SUMMARY OF THE INVENTION

With the foregoing in mind, it is a purpose of this invention to provide a solution which enables a user desiring a 1 U server to obtain such a product while providing an improvement path which enables steps upward between the 1 U and 2 U embodiments. In realizing this purpose of this invention, an enclosure for a rack mounted server is assembled using upper and lower housings which are adjustable one relative to the other to provide increases in enclosure height by fractional increments of 1 U. By providing for fractional growth in height, a user is enabled to upgrade processor and memory without the necessity of replacing the entirety of a server system which is in use.

### BRIEF DESCRIPTION OF DRAWINGS

Some of the purposes of the invention having been stated, others will appear as the description proceeds, when taken in connection with the accompanying drawings, in which:

FIG. 1 is a perspective view of a rack mounted device embodying the present invention;

FIGS. 2A, 2B and 2C are schematic end elevation views, from the front, of the device of FIG. 1 showing expansion of the housing from a collapsed position (FIG. 2A) to first and second expanded positions (FIGS. 2B and 2C); and

FIGS. 3A, 3B and 3C are schematic side elevation views, from the right, of the device of FIGS. 1 and 2 showing expansion of the housing from a collapsed position (FIG. 3A) to first and second expanded positions (FIGS. 3B and 3C).

### DETAILED DESCRIPTION OF INVENTION

While the present invention will be described more fully hereinafter with reference to the accompanying drawings, in which a preferred embodiment of the present invention is shown, it is to be understood at the outset of the description which follows that persons of skill in the appropriate arts may modify the invention here described while still achieving the favorable results of the invention. Accordingly, the description which follows is to be understood as being a broad, teaching disclosure directed to persons of skill in the appropriate arts, and not as limiting upon the present invention.

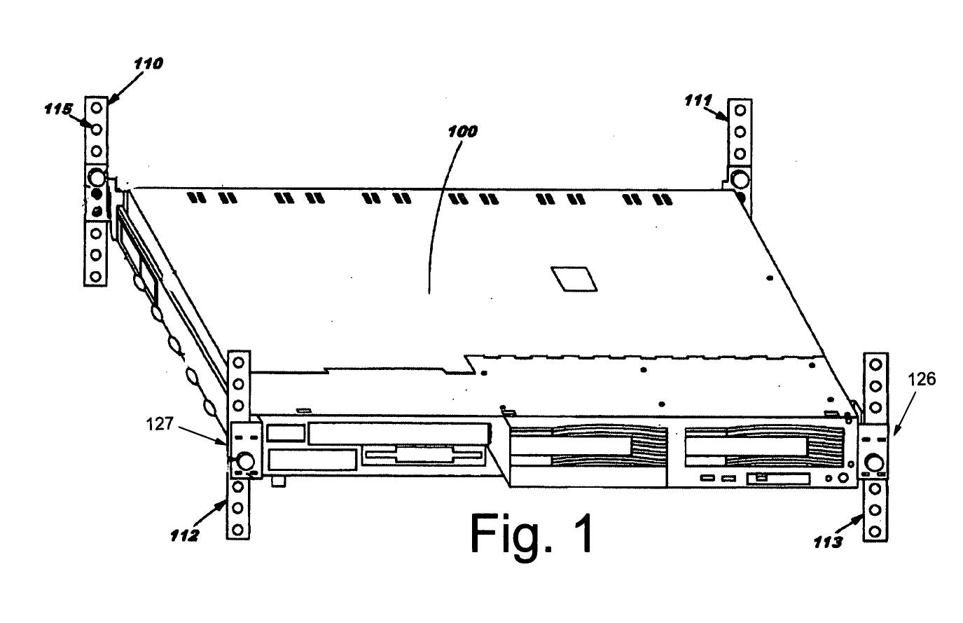

Referring now more particularly to the accompanying drawings, FIG. 1 illustrates one example of a rack and a rack mounted enclosure for a digital data processing element. Most commonly, the processing element is a server computer system, configured with a printed circuit board known as a motherboard and sockets which accept other boards or cards which mount processors, memory and input/output (I/O) adapters. However, the processing elements may have other functions than server computer systems, such as telecommunications switches or the like. The present invention contemplates that the mechanical enclosures here disclosed may serve to enclose electrical elements of a wide variety of types and utilities.

A rack mounted complex includes several enclosures (one of which is shown at 100), to be described more fully hereinafter. The enclosures are mounted in a rack provided by a set of spaced uprights 110, 111, 112, 113 which have a series of vertically spaced holes 115 formed in them. The spacing of the uprights one from another and of the holes along them are to a standard, to accommodate enclosures of standard dimensions. Typically, a rack mount intended to be filled or partially filled with 1 U enclosures will have a spacing which is intended to limit the choice of enclosures to be mounted to those that are 1 U, posing a problem for users who may encounter the need of replacing 1 U servers.

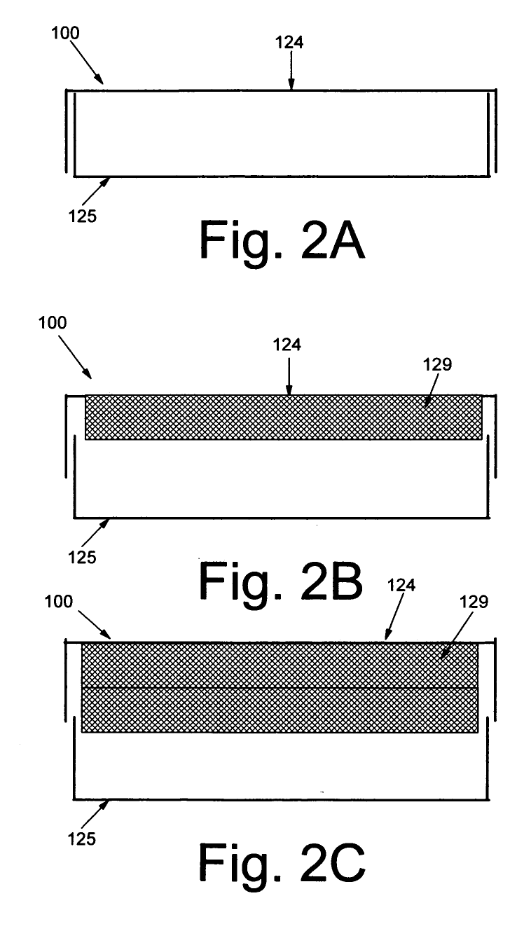

Each enclosure 100 has, as shown in FIG. 2, an upper housing 124 and a lower housing 125 engaging the upper housing. The upper and lower housings together define the enclosure 100 for a digital data processing element as described above, the enclosure having height, predetermined width, and predetermined depth. The width and depth meet the standard for the spacing of the uprights 110, 111, 112, 113 of the rack into which the enclosure is to be mounted. The upper and lower housings 124, 125 are adjustable one relative to the other to vary the height of the enclosure from a collapsed condition toward an extended condition by defined increments.

The enclosure has right and left mounting ears 126, 127 (FIG. 1) projecting widthwise from opposing sides with the mounting ears defining mounting openings of a size and spacing to align with the holes or mounting openings 115 along the uprights in a standard rack mount for electronic devices. Here, each ear 126, 127 has at least one hole, enabling the use of fasteners to secure the enclosure in a rack mount. The spacing of the openings in the uprights defines preferred increments by which the height of the enclosure is adjusted.

In the illustrated design for the enclosure mechanicals, this spacing opens the possibility of expanding the height of the enclosure by the amount of one or two hole spacings. That is, the height may be expanded by ⅓ U in each of two steps, if the full capability of the invention is exercised. It should be understood when referring to enclosures specified in increments or fractions of U that the actual enclosure dimensions should be less to maintain appropriate mechanical tolerances. Thus the enclosure may house processing elements at 1 U height (FIG. 2A), at 1 and ⅓ U height (FIG. 2B), and at 1 and ⅔ U height (FIG. 2C) for a standard rack with three mounting holes for each 1 U space. With this capability, secondary or daughter cards or boards or greater heights may be accommodated, enabling the installation of higher capability processors, memory and I/O adapter cards. The 1 U configuration is here referred to as the collapsed condition, with the greater height positions being referred to as expanded conditions. While described with reference to a 1 U enclosure, the invention is equally applicable to enclosures of 2 U or more.

Other embodiments can support other rack standards which may exist or be developed in the future, with fewer or more than three holes per U. For rack standards with two holes per U, increments of 1 U and 1 and ½ U can be supported. For rack standards with four holes per U, increments of 1 U, 1 and ¼ U, 1 and ½ U and 1 and ¾ U can be supported. The same pattern can be extended to more holes per U. As another example, a 2 U enclosure with a rack with three holes per U could accommodate enclosures which vary by ⅓ U from 2 U to 3 and ⅔ U. A 1 U enclosure can indeed grow beyond 1 and ⅔ U and a 2 U beyond 3 and ⅔ U with an upper housing whose sides are themselves extendible or by replacing the upper housing with a taller one while retaining all other components.

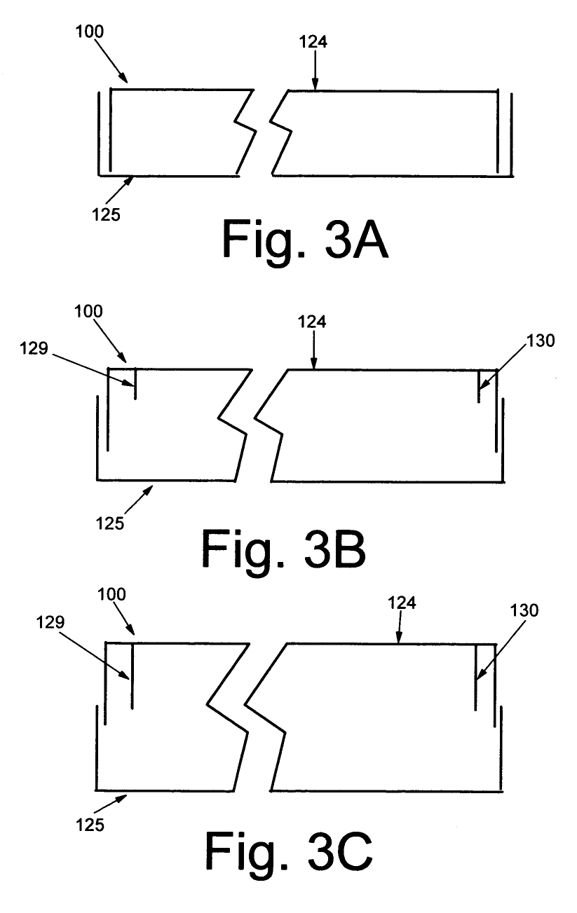

Returning to the preferred embodiment of the present invention, in order to provide ventilation while protecting against undesirable entry of foreign objects and materials, folding end plates 129, 130 are mounted on the upper housing 124. The end plates are retracted against the inner surface of the upper housing 124 when the enclosure is in the collapsed condition, by means of a pivotal connection to the housing. As the upper housing is raised relative to the lower housing to expand the enclosure, the end plates pivot downwardly to take positions shown in FIGS. 2B, 3B, 2C and 3C. FIGS. 2B and 3B illustrate the enclosure in the 1 and ⅓ expanded position; FIGS. C and 3C, the 1 and ⅔ expanded position.

The housings may be made in a number of ways to accommodate the expanding movement and positioning here described. Fasteners such as screws or bolts may be used to secure the housings in collapsed and expanded positions, or clips formed in the material of the housings may secure them in a tool less manner in their relative position.

In the drawings and specifications there has been set forth a preferred embodiment of the invention and, although specific terms are used, the description thus given uses terminology in a generic and descriptive sense only and not for purposes of limitation.

What is claimed is:

1. Apparatus comprising:
an upper housing;
a lower housing engaging said upper housing;
said upper and lower housings together defining an enclosure for a digital data processing element, said enclosure having height, predetermined width, and predetermined depth;
right and left mounting ears projecting widthwise from opposing sides of said enclosure;
said mounting ears defining mounting openings of a size and spacing to align with mounting openings in a standard rack mount for electronic devices;
said upper and lower housings being adjustable one relative to the other to vary the height of said enclosure from a collapsed condition toward an extended condition by increments determined by the spacing between said mounting openings defined by said mounting ears.

2. Apparatus according to claim 1 wherein said upper and lower housings are adjustable one relative to the other to increase the height of said enclosure by a fraction of the height of said enclosure when in the collapsed condition.

3. Apparatus according to claim 1 wherein said upper and lower housings are adjustable one relative to the other to increase the height of said enclosure by one third of the height of said enclosure when in the collapsed condition.

4. Apparatus according to claim 1 wherein said upper and lower housings are adjustable one relative to the other to increase the height of said enclosure by two thirds of the height of said enclosure when in the collapsed condition.

5. Apparatus according to claim 3 wherein said upper and lower housings are adjustable one relative to the other to increase the height of said enclosure by two thirds of the height of said enclosure when in the collapsed condition.

6. Apparatus according to claim 1 further comprising front and rear end plates pivotally mounted to said upper housing and positionable in a retracted position when said enclosure is in the collapsed condition and in an extended position when said enclosure is in the extended position.

7. Apparatus according to claim 6 wherein each of said end plates is formed in a plurality of pivotally connected portions, one of which accommodates expansion of said enclosure to a height of a first fraction more than the height of said enclosure when in the collapsed condition and a second of which accommodates expansion of said enclosure to a height of a second, larger, fraction more than the height of said enclosure when in the collapsed condition.

8. Apparatus according to claim 1 wherein said upper housing has side walls which are extensible for varying the enclosed height of said enclosure.
